(19) United States
(12) Patent Application Publication
(10) Pub. No.: US 2008/0014445 A1
(43) Pub. Date: Jan. 17, 2008

(54) Chamberless Plasma Deposition of Coatings

(75) Inventors: Robert F. Hicks, Los Angeles, CA (US); Gregory R. Nowling, San Jose, CA (US)

Correspondence Address: CANADY & LORTZ LLP, 2540 HUNTINGTON DRIVE, SUITE 205, SAN MARINO, CA, 91108, US

(73) Assignee: The Regents of the University of California, Oakland, CA (US)

(21) Appl. No.: 11/571,238

(22) PCT Filed: Jun. 24, 2005
(86) PCT No.: PCT/US05/22788

§ 371 Date: Dec. 22, 2006

Related U.S. Application Data
(60) Provisional application No. 60/582,634, filed on Jun. 24, 2004.

(51) Int. Cl. B05D 1/08; B32B 17/00; C23C 16/40; C23C 4/00; C23C 4/04; C23C 4/10; H05H 1/26

(52) U.S. Cl. 428/409; 118/723 R; 427/446

(57) ABSTRACT

A system and method of depositing coatings on a substrate includes providing a substrate in contact with air, and providing a plasma source (12) having a housing (16) surrounding a first electrode (18) and a second electrode (20) spaced from the first electrode. A plasma is generated by applying a signal to the first electrode and exciting a gas between the first electrode and the second electrode. A substantially uniform flux of at least one reactive specie is generated over an area larger than 1 cm². The plasma is emitted into the air and toward the substrate. Various embodiments of the system and method allow high speed deposition of coatings on even thermally-sensitive substrates without the need of a chamber enclosing the substrate.

### CROSS-REFERENCE TO RELATED APPLICATION

This application is based on and claims priority of U.S. Provisional Application No. 60/582,634, filed Jun. 24, 2004, the entire disclosure of which is incorporated by reference herein.

### ACKNOWLEDGEMENT OF GOVERNMENT SUPPORT

This invention was made with government support under grant no. DE-FG07-00ER45857, awarded by the Department of Energy, and grant no. CTS-9821062, awarded by the National Science Foundation. The Government has certain rights in the invention.

### BACKGROUND OF THE INVENTION

Plasma-enhanced chemical vapor deposition (PECVD) can be used for depositing thin films onto substrates. In PECVD techniques, a plasma is generated by exciting ions within a gas flow between two electrodes. The plasma provides reactive species that decompose a volatile chemical precursor that is combined with it and directed toward a substrate, thereby depositing a thin film of a material onto the substrate.

One PECVD system is disclosed in Babayan et al, “Deposition of silicon dioxide films with an atmospheric-pressure plasma jet,” Plasma Sources Sci. Technol. 7 (1998), pp. 286-288. In this system, oxygen and helium gasses are input into an annular space between two electrodes, one of the electrodes driven by a radio frequency. When enough power is applied to this electrode, the gasses are ionized to make a plasma. The plasma generates reactive oxygen atoms and other radicals, which flow out of a small nozzle at the end of the annular space. The nozzle is approximately 4-6 mm in diameter. At the nozzle, a small tube injects a silicon-based chemical precursor, such as tetraethoxysilane (“TEOS”), to mix with the radicals from the plasma. The TEOS decomposes to deposit a thin film on the substrate. The substrate is Si (100) and is located in air at ambient conditions.

Advantages to this system are that it can be operated on substrates that are exposed to air at normal atmospheric pressure, and that temperature of the deposited film can be as low as 115° C. Placing the substrate in normal, ambient conditions may allow for continuous, in-line processing of substrates without the costly expenses of enclosing the substrates within a chamber. Further, low film temperature allows thermally sensitive substrates, such as plastics, to be processed without alteration. Despite these advantages, however, this system has a slow deposition rate of around 20-70 nm/min, with a maximum measured rate of 300 nm/min. Further, this system cannot deposit uniform films over large substrates, such as a piece of paper, as the area on which the film is deposited is a dot slightly larger than the nozzle, or around 1 cm². Even if the system is moved across the substrate like a paint brush, the deposition rate is slow and the coating lacks uniformity. Efforts made to increase the size of the nozzle to a channel have proven unsuccessful.

A second PECVD system is disclosed in Nowling, et al., “Remote plasma-enhanced chemical vapour deposition of silicon nitride at atmospheric pressure,” Plasma Sources Sci. Technol. 11 (2002) 97-103 and. This system includes a chamber surrounding a substrate and a plasma source. Air is pumped out of the chamber and it is refilled with nitrogen and helium. The plasma source includes two substantially parallel electrode screens with perforations through which nitrogen and helium gasses flow. Moravej, et al., “Plasma enhanced chemical vapour deposition of hydrogenated amorphous silicon at atmospheric pressure,” Plasma Sources Sci. Technol. 13 (2004) 8-14, teaches that hydrogen gasses may be substituted for nitrogen gasses in this system. A plasma is generated from the gasses and reactive nitrogen or hydrogen atoms are combined with silane between or downstream from the electrode screens. The silane is thereby decomposed to deposit silicon dioxide or amorphous silicon onto the substrate within the chamber. A disc-shaped silicate film was obtained in this system over a diameter of about 32 cm at a rate of about 0.1 μm/minute. The film was substantially uniform across the substrate. U.S. Published Application No. U.S. 2002/0129902 A1 also teaches that TEOS can be used as in place of silane in this system to form silicate glass.

Advantages to this system are that the plasma source can generate a substantially uniform flux of one or more reactive specie over an area larger than 1 cm², deposition rates are typically higher than those in the earlier systems, and temperatures of the coating are low enough to process thermally sensitive substrates, such as those containing plastics. Disadvantages of this system, however, are that a chamber is needed around the substrate to isolate the substrate and the flux of the reactive species from air. Silane, in particular, is pyrophoric, and may ignite when put in contact with air. Such chambers can limit the possibilities of continuous in-line coating of substrates, so that the entire system must be located within a chamber. Such a chamber also prevents the system from being easily portable. Consequently, applications such as applying glass coatings to plastic windows on airplanes, walls, etc., are not feasible within such a chamber-based system.

### SUMMARY OF THE INVENTION

A system for deposition of coatings includes a substrate in contact with air, a plasma source, and a volatile precursor. The plasma source has a housing surrounding a first electrode and a second electrode spaced from the first electrode. The first electrode is electrically coupled to a signal generator such that a gas flow between the first electrode and the second electrode is excited to create a plasma. A substantially uniform flux of at least one reactive specie over an area larger than 1 cm², which is emitted from the housing toward the substrate. A volatile precursor is combined with the substantially uniform flux such that the volatile precursor is decomposed to deposit a substantially uniform coating on the substrate.

In various embodiments of this system, the volatile precursor is a nonpyrophoric metal organic precursor, and the coating is an inorganic oxide. For example, an organosilane precursor can be used. The volatile precursor can include silicon combined with a ligand containing oxygen, carbon, hydrogen, and/or nitrogen, and the coating would be glass. In some embodiments, the volatile precursor is chosen from a group consisting of: hexamethyldisilazane, hexamethyldisiloxane, tetramethyldisiloxane, tetramethylcyclotetrasiloxane, and tetraethoxysilane.

In some embodiments of this system, the substrate is plastic or an other thermally sensitive material, and the substantially uniform flux is at a temperature of less than 250° C. Other nonlimiting examples of substrates comprise wood, metal, semiconducting material, and/or glass. Advantageously, in some embodiments, the plasma deposition takes place at substantially atmospheric pressure.

In another aspect of the invention, a method of depositing a coating on a substrate includes providing a substrate in contact with air, and providing a plasma source having a housing surrounding a first electrode and a second electrode spaced from the first electrode. A plasma is generated by applying a signal to the first electrode to excite a gas between the first electrode and the second electrode. A substantially uniform flux of at least one reactive specie is generated over an area larger than 1 cm². The plasma is emitted into the air and toward the substrate. A coating is then deposited on the substrate.

In one embodiment, the coating is deposited by combining a volatile precursor with the substantially uniform flux such that the volatile precursor is decomposed to deposit a substantially uniform coating of glass on the substrate. The volatile precursor may be chosen from the group consisting of: hexamethyldisilazane, hexamethyldisiloxane, tetramethyldisiloxane, tetramethylcyclotetrasiloxane, and tetraethoxysilane.

In some embodiments, the coating is deposited at a rate above 0.3 μm/minute on the substrate. The substantially uniform flux may be at a temperature of less than 250° C. The substrate may also include plastic and other thermally-sensitive materials. The substrate may also be in substantially atmospheric pressure.

Numerous useful objects can be produced by these techniques. Continuous in-line glass coating of substrates, for example along a conveyer belt, can be accomplished without the expense and immobility of a chamber system. The chamberless plasma deposition system may also be made into a portable device to allow for deposition of glass on large objects, such as installed airplane windows, walls, etc. The chamberless plasma deposition system and method may also be used with thermally sensitive substrates, which can be highly advantageous for deposition of glass on, for example, plastic housings of cellular phones, PDAs, digital cameras, and other handheld devices.

### BRIEF DESCRIPTION OF THE DRAWINGS

FIG. 1 is a schematic illustration of a plasma reactor for deposition of glass on air-exposed substrates, showing a cutaway view of a plasma device according to a first embodiment of the invention.

FIG. 2 is a flowchart illustrating one embodiment of a method according to the invention.

FIG. 3 is a graph showing the dependence of the deposition rate on precursor partial pressures, according to various embodiments of the invention.

FIG. 4 is a graph showing infrared spectra of silicon dioxide films grown according to an embodiment of the invention with HMDSN at (a) 0.023 μm/minute and (b) 0.24 μm/minute.

FIG. 5a is a graph showing infrared spectra of films deposited according to various embodiments of the invention between 450 and 2500 cm⁻¹.

FIG. 5b is a graph showing infrared spectra of films deposited according to various embodiments of the invention between 2500 and 4000 cm⁻¹.

FIG. 6 is a graph showing the dependence of the OH peak area relative to the deposition rates according to various embodiments of the invention.

FIG. 7 is a graph showing film porosity as a function of deposition rate according to various embodiments of the invention.

FIG. 8a is a three-dimensional surface image of a film grown according to one embodiment of the invention.

FIG. 8b is a magnified image of the surface shown in FIG. 8a.

FIG. 9a is a three-dimensional surface image of a film grown according to another embodiment of the invention.

FIG. 9b is a magnified image of the surface shown in FIG. 9a.

FIG. 10 is a graph showing linear scratch density relative to thickness, at different deposition rates, according to an embodiment of the invention.

FIG. 11 is a graph showing linear scratch density relative to thickness, at different deposition rates, according to another embodiment of the invention.

### DETAILED DESCRIPTION OF THE INVENTION

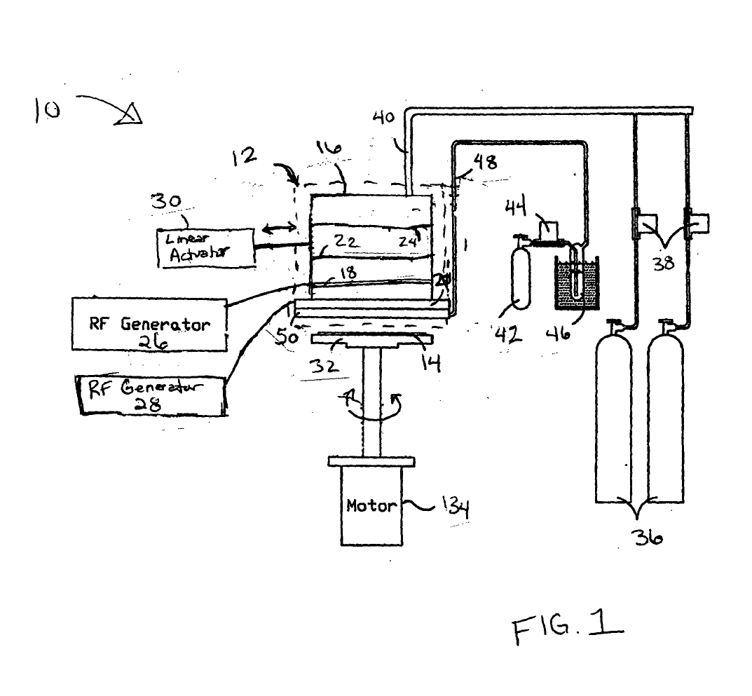

According to a first aspect of the invention, a system for deposition of a coating on a substrate is provided, and comprises a substrate in contact with air, a plasma source, and a volatile precursor. The plasma source has a housing surrounding a first electrode and a second electrode spaced from the first electrode. The first electrode is electrically coupled to a signal generator such that gas between the first electrode and the second electrode is excited to form a plasma. The plasma is emitted from the housing toward the substrate and generates a substantially uniform flux of at least one reactive specie over an area larger than 1 cm². A volatile precursor is combined with the substantially uniform flux such that the volatile precursor is decomposed to deposit a substantially uniform coating on the substrate. Advantageously, in most embodiments, the deposition takes place in air at substantially atmospheric pressure and without resort to a chamber of vacuum apparatus. A nonlimiting example of such a system is shown in FIG. 1.

A plasma deposition reactor system 10 includes a plasma source 12 and a substrate 14 in contact with air. The plasma source 12 has a housing 16 that contains conductive electrodes 18, 20 spaced apart from each other. The electrodes 18, 20 have openings, or perforations, to allow gas to flow through or around them. Perforated sheets 22, 24 are also within the housing to allow a uniform flow of gas through the housing. One or both of the electrodes 18, 20 are driven by RF generators 26, 28, or any device capable of applying a signal. A linear actuator 30 is coupled to the plasma source 12 to oscillate the source over the substrate 14.

The air-exposed substrate 14 is placed downstream of the plasma source on a substrate stage 32. A motor 18 is electrically coupled to the substrate stage 32 to rotate the stage at a desired frequency.

Cylinders 36, containing process gasses such as oxygen and helium, are coupled to the housing 16 through tube 40. Mass controllers 38 are coupled to the tube 40.

Cylinder 38, containing a carrier gas, is coupled to a mass flow controller 44, a bubbler 46 containing a volatile chemical precursor, and a tube 48, which leads to a showerhead 50 downstream of the plasma source 12.

In operation, the process gasses flow out of the cylinders 36, through the mass controllers 38 and into the housing 16 through tube 40. The gas is ionized between the electrodes 18, 20 within the housing 16 to form a plasma. The plasma emerges from the housing 16 through the bottom electrode 20 to create a substantially uniform flux of at least one reactive specie.

The carrier gas flows out of the cylinder 42, through the mass flow controller 44, and into the bubbler 46 containing the volatile chemical precursor. A temperature-control bath maintains a predetermined vapor pressure of the precursor. The precursor, borne by the carrier gas, is then input through the tube 48 and the showerhead 50 to combine with the substantially uniform flux emerging from the bottom electrode. The combination is then directed into the air between the plasma source 12 and the substrate 14 and toward the substrate 14.

This chamberless plasma deposition reactor system 10 can be used to deposit coatings on a wide variety of substrates, such as paint, paper, fabric, wood, semiconducting material, glass, etc., and even thermally sensitive substrates, such as those containing plastic, polycarbonate, plexiglass, etc. Nonlimiting examples of coatings include inorganic oxides, such as silicon dioxide glass and transitional metal oxides. Inorganic oxide coatings can comprise oxygen and one or more elements selected from the group silicon, aluminum, gallium, indium, tin, lead, bismuth, zinc, cadmium, copper, silver, nickel, palladium, cobalt, iron, manganese, chromium, molybdenum, tungsten, vanadium, niobium, tantalum, titanium, zirconium, hafnium, scandium, yttrium, lanthanum, cerium, beryllium, and magnesium.

Because the substrate can be in contact with air and the substantially uniform flux is over 1 cm², a uniform coating can be deposited at a high rate and without the need for a chamber. Thus, instead of the immobile, fixed systems that can coat only substrates that will fit within their chambers, the system shown in this embodiment can be portable, used in an air-exposed assembly line, or on any number of large or immobile substrates. Further, because the temperature of the coatings can be less than 250° C., thermally sensitive substrates can be coated, such as plastics.

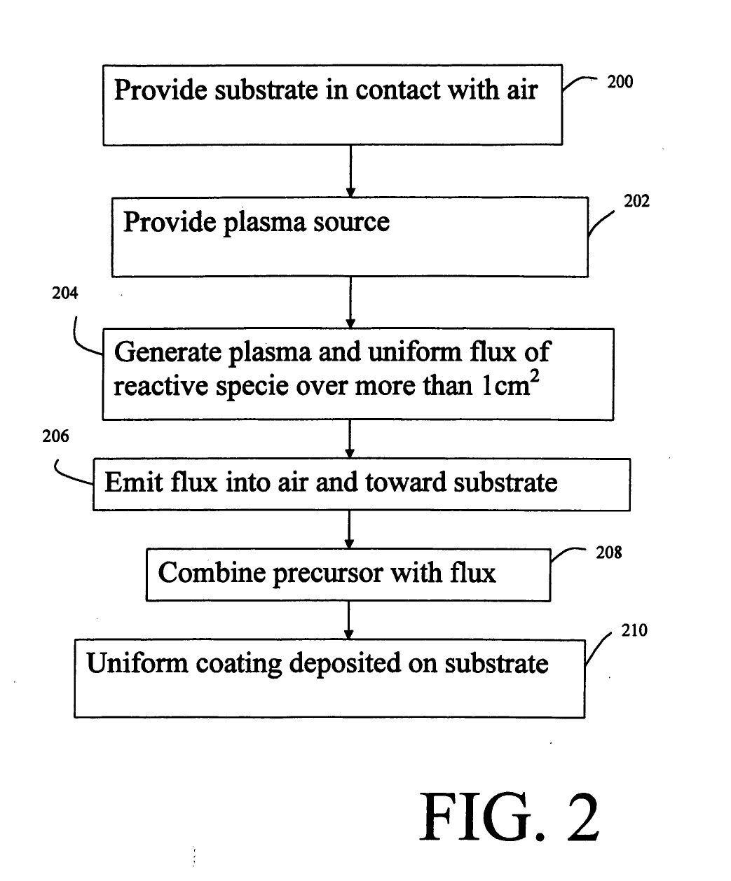

FIG. 2 shows process steps of one embodiment of a method for depositing a glass coating on a substrate according to the invention. A substrate is provided at 200 that is in contact with air. A plasma source is provided at 202 that has a housing surrounding a first electrode and a second electrode that is spaced from the first electrode. A plasma is generated at 204 by applying a signal to the first electrode to excite gas between the first electrode and the second electrode such that a substantially uniform flux of at least one reactive specie is generated over an area larger than 1 cm². The flux is emitted into the air and toward the substrate at 206. At 208, a volatile precursor is combined with the substantially uniform flux so that the volatile precursor is decomposed to deposit a substantially uniform coating on the substrate at 210.

The organosilane precursor used in the system tends to have a large impact on the deposition rate, composition, and mechanical properties of the material. In some embodiments, materials closely resembling SiO₂ with minimal hydroxyl and carbon impurities, are deposited on the substrate, and provide effective hardness and abrasion resistance. Silazane precursors can produce these materials at high deposition rates.

Five silicon precursors were examined in the chamberless plasma deposition reactor system 10 shown in FIG. 1 and tested for film growth rate, composition, and hardness. The test results are discussed below.

Test Methods and Results

The plasma source 12 used in the study was an Atmoflo™ 250D coating tool from Surfx Technologies LLC, which is substantially the same as that disclosed in U.S. Patent Application Publication No. U.S. 2002/0129902 A1, the entire content of which is incorporated herein by reference. A mixture of oxygen (2.0 vol %) and helium was fed to the capacitive discharge plasma that was driven by 100 W of radio frequency power at 27.12 MHz, but other driving powers and frequencies may also be used. The precursor was introduced separately in a helium carrier gas to the showerhead 50, just below the lower electrode 20. In this embodiment, the area of the showerhead was 5.1 cm², but a wide range of showerheads and electrode sizes and shapes are possible according to the size of the desired coating. The total flow rate of the gasses was 30.6 liters/minute at 25° C. and at 1 atm. The substrate 14 was placed in contact with air 2.75 mm downstream of the showerhead 50 and spun at a rate of 6.0 rpm. Alternatively, other spin rates may be used. The linear actuator 30 oscillated the plasma source horizontally by ±2.25 mm over the rotating substrate 14 at a rate of 3.9 mm/s. The substrate 14 was not heated other than by the plasma gas.

The five silicon precursors studied were hexamethyldisilazane (HMDSN), hexamethyldisiloxane (HMDSO), tetramethyldisiloxane (TMDSO), tetramethylcyclotetrasiloxane (TMCTS) and tetraethoxysilane (TEOS). Selected properties of each precursor are listed in Table 1.

TABLE 1

| | | | Bubbler | Vapor |
|---|---|---|---|---|
| | Molecular | Chemical | Temp | Pressure |
| Name | Weight | Formula | (° C.) | (Torr) |
| Hexamethyldisilazane | 161.4 | C₆N₁₉NSi₂ | 20 | 20.2 |
| Hexamethyldisiloxane | 162.4 | C₆H₁₈OSi₂ | 7 | 16.58 |
| Tetramethyldisiloxane | 134.3 | C₄H₁₄OSi₂ | 7 | 75.6 |
| Tetramethylcyclotetra- | 240.5 | C₄H₁₆O₄Si₄ | 10 | 2.75 |
| siloxane | | | | |
| Tetraethoxysilane | 208.3 | C₄H₂₀O₄Si | 17 | 1.15 |

The vapor pressures of TMCTS, TEOS, and HMDSN were taken from product literature, e.g., MSDS from Schumacher 2002 and Mallinckrodt, Inc., 2001. The vapor pressures of TMDSO and HMDSO at the bubbler temperatures were estimated using the Clausius-Clapeyron equation and published vapor pressures at other temperatures, e.g., MSDS from Sigma-Aldrich 2002. The substrates 14 tested were n-type Si (100) squares, 3.8×3.8 cm².

Deposition Rates

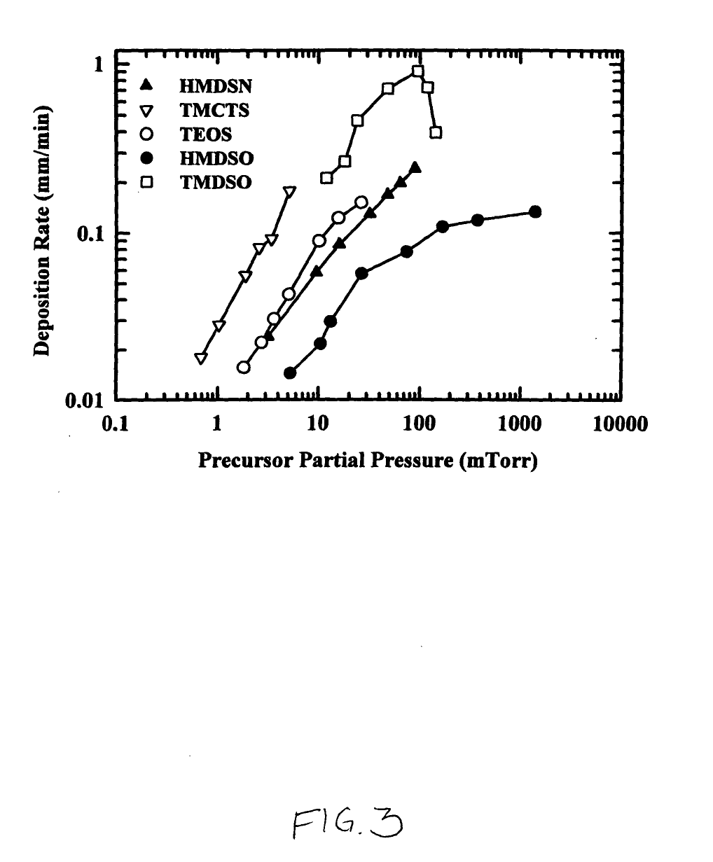

FIG. 3 shows the deposition rates observed for each of the five precursors, plotted as a function of their partial pressure in the feed. The inlet pressures were varied by changing the helium flow rate through the bubbler, while holding the bath temperature constant at the values listed in Table 1. The maximum flow rates through the bubblers were 50 sccm for TMDSO, 120 sccm for HMDSN and HMDSO, and 1000 sccm for TMCTS and TEOS. It is assumed that, at these flow rates, the vapor achieved saturation in the helium carrier gas.

The deposition rates are shown to vary based on the specific precursor fed to the process. The growth rates observed with TMCTS, TEOS, HMDSN, and HMDSO increase from about 0.015 to 0.2 μm/min with increasing precursor partial pressure. In the case of TMCTS, TEOS, and HMDSN, the rates are approximately proportional to the amount of precursor fed. However, for HMDSO, the rate gradually levels off at higher partial pressures. In contrast, the growth rate obtained with TMDSO varies from 0.2 to 1.0 μm/min as the partial pressure increases from 10 to 100 mTorr. Above 100 mTorr, the deposition rate decreases with the TMDSO partial pressure.

Over the range of the deposition rates shown in FIG. 3, there is no noticeable degradation in the coating properties. With TMCTS and HMDSN, rates higher than 0.18 and 0.24 μm/min yield films with a white, chalky appearance. For TEOS, the films crack shortly after deposition at rates above 0.2 μm/min. Coatings deposited using TMDSO at a partial pressure above 140 mTorr exhibit a tacky texture and are easily removed with tape.

The incorporation efficiency of the precursors into the glass films varies widely, as evidenced by the broad range of partial pressures examined for the process. This efficiency, which may be defined as the ratio of the moles of silicon in the film to the moles of precursor fed to the flux, is highest for TMCTS and TEOS, and lowest for HMDSO. In the case of TMCTS, this value increases from 7.2% to 9.6% as the growth rate rises from 0.02 to 0.18 μm/min. However, for TEOS, this trend reverses and the efficiency falls from 9.4% to 6.3% as the rate increases from 0.016 to 0.15 μm/min. With HMDSO, the incorporation efficiency ranges from 1.5% to 0.05% at growth rates between 0.014 and 0.13 μm/min. For HMDSN and TMDSO, the average incorporation efficiencies are 2.8% and 6.6%, respectively.

In the deposition rate test, an ellipsometer (SCI FilmTek 2000™) was used to measure the film thickness and the refractive index at λ=632 nm. The values obtained were averages of 15 data points across the film. The standard deviation of the thickness was ±8%. The deposition rate was determined by dividing the average film thickness by the process time. The film thickness obtained via this technique was verified using a step profiler (Veeco Instruments Dektak 8™). The step was created by coating half of the film with a silicone adhesive sealant (GE Translucent RTV 108™) and etching the unmasked region away by immersing the sample in a 10% HF solution. Finally, the adhesive was removed with acetone. Several films of varying thicknesses and compositions were tested in this fashion, and all exhibited thicknesses within the standard deviation of the values determined by ellipsometry.

Film Composition and Structure

The refractive index measured for the SiO₂ films does not show a strong dependence on the precursor type and partial pressure. A value of 1.47±0.03 is observed for TMCTS, TEOS, HMDSO, and HMDSN. This refractive index is consistent with that reported for SiO₂ films deposited in low-pressure PECVD processes. On the other hand, films produced from TMDSO at rates exceeding 0.7 μm/min exhibit a refractive index of 1.41±0.02. Other studies of SiO₂ PECVD have recorded a similar drop in the refractive index, and have ascribed it to silicon-carbon bonds and voids in the films.

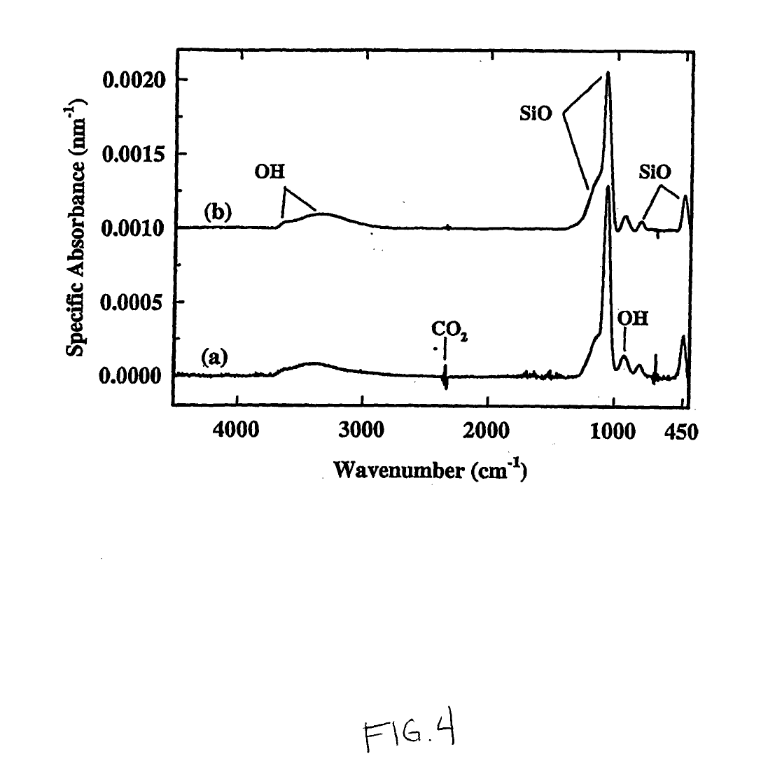

Infrared absorbance spectra of films deposited with HMDSN at rates of 0.023 (a) and 0.24 μm/minute (b) are presented in FIG. 4. The specific absorbance was obtained by dividing −log(I/I₀) by the film thickness. The peaks at 1075, 800, and 450/cm are due to the asymmetric stretching, bending, and rocking modes of siloxane bridges. The broad shoulder at approximately 1150/cm is also due to the stretching modes of the siloxane bridges. As is common with SiO₂ films grown at reduced temperatures, the IR spectra also contain features attributed to hydroxyl groups. The peak at 930/cm is due to O—H deformations, while the broad band and shoulder at 3400 and 3650/cm are due to O—H stretching vibrations of hydrogen-bonded and isolated hydroxyl groups. Examination of the spectra in the figure reveals that no C—O, Si—H or C—H stretching modes at 1750, 2250 or 2900/cm are detected at either deposition rate.

Subtle difference are evident in the IR spectra of the glass films grown with HMDSN at the low and high deposition rates. The total area of the hydroxyl band between 2600 and 3600/cm is 20% larger for the film deposited at 0.24 μm/minute. Furthermore, the center of this band is shifted 60/cm to lower wavenumbers, presumably owing to increased contributions from hydrogen-bonded OH groups. The frequency of the Si—O—Si stretching vibration is 1070/cm at 0.023 μm/minute, compared with 1082/cm at 0.24 μm/minute. Furthermore, the area of this peak is 26% smaller, while the high-frequency shoulder is 240% larger, for the higher growth rate compared with the lower one. These changes in the Si—O stretching modes are an indication of a slightly increased porosity in the SiO₂ film.

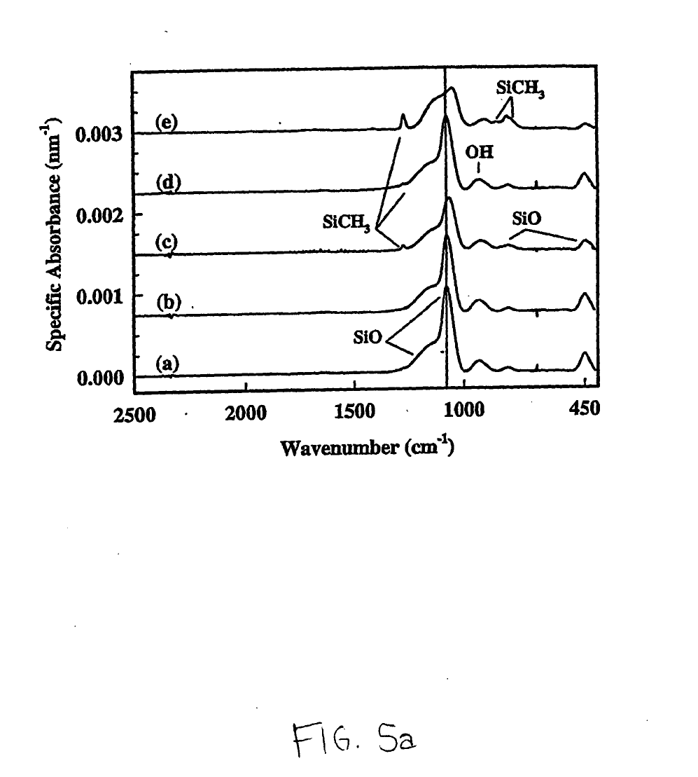

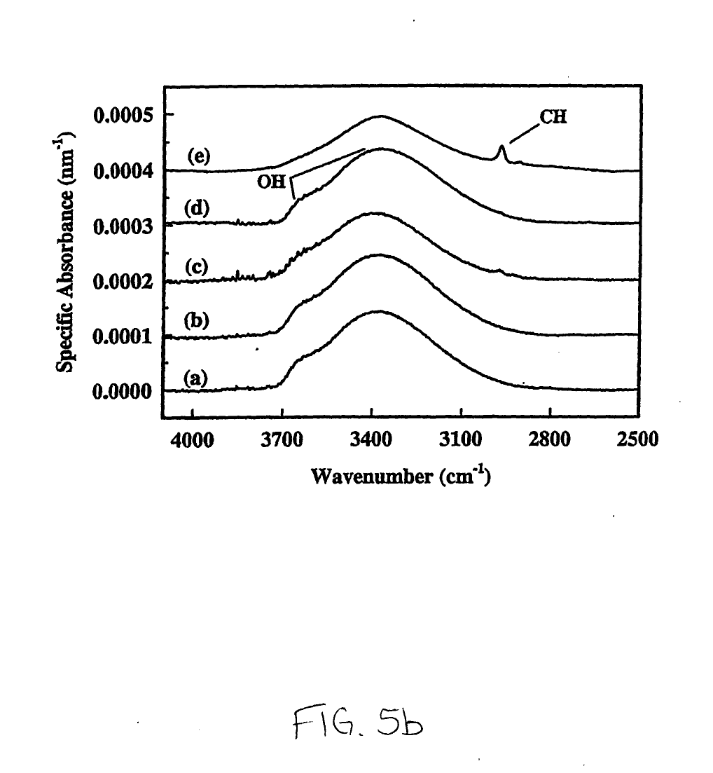

Infrared spectra of films deposited with TMCTS (a), TEOS (b), and HMDSO (c) at their respective maximum deposition rates of approximately 0.15 μm/minute are shown in FIGS. 5a and 5b, along with spectra for films grown with TMDSO at rates of 0.21 (d) and 0.91 μm/minute (e). The material deposited from TEOS and TMCTS exhibits O—H and Si—O—Si vibrations at 3650, 3400, 1150, 1075, 800 and 450/cm, which are characteristic of PECVD silicon dioxide. On the other hand, with TMDSO and HMDSO, a C—H bending mode is observed at 1275/cm, which is due to the presence of methyl groups attached to silicon. Further, the C—H stretching modes observed at approximately 2900/cm is shown in FIG. 5b. These features are not present in films grown at rates at or below 0.10 μm/minute with HMDSO. The IR spectra of films deposited at the maximum growth rate with TMDSO show a distribution of bands that are significantly different from those shown by the spectra of the other films. In particular, the siloxane peaks at 1075, 800, and 450/cm are greatly reduced in intensity, while the shoulder at 1150/cm is broader and more intense. Small peaks are discernible at 840 and 780/cm as well. These changes are attributed to increased porosity and methyl-silicon bonding in the films.

Hydroxyl impurities are present in all the films deposited with the organosilane precursors. Since these groups weaken the glass-like structure of the coatings, they represent an important basis for comparison. The hydroxyl could either be incorporated into the films during growth or be the result of moisture uptake from the air after the samples were deposited.

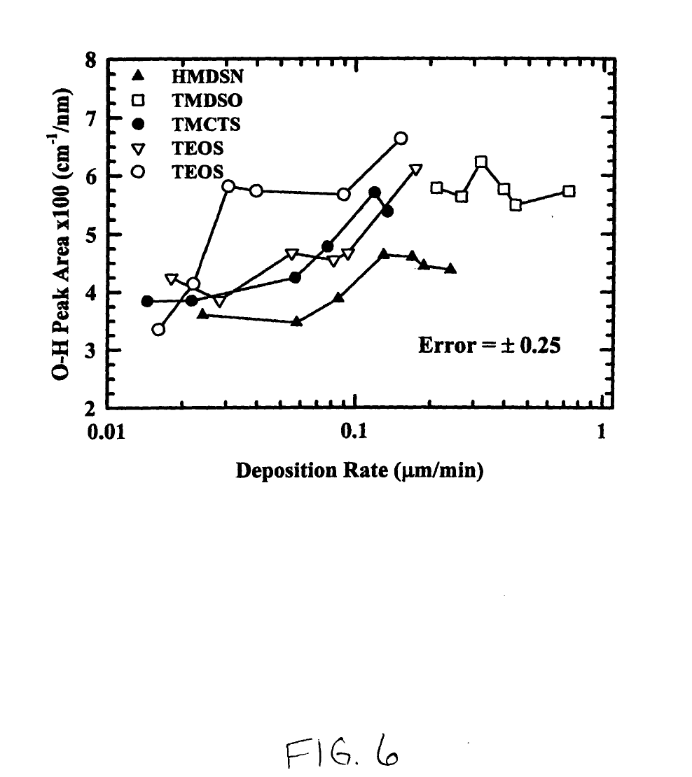

As shown in FIG. 6, the hydroxyl content correlates with the porosity of the films. Integrated peak areas of the hydroxyl stretching bands between 2700 and 3775/cm are shown. A general trend of increasing hydroxyl content with deposition rate is apparent. For films deposited with TMDSO, the OH peak areas range from 0.055 to 0.063. For films deposited with TEOS, the OH peak area ranges from 0.03 at 0.016 μm/minute to 0.07 at 0.15 μm/minute. In contrast, films grown using HMDSN had slightly lower hydroxyl content, i.e., peak areas of 0.035 and 0.045 and showed a much weaker dependence on deposition rate. The hydrogen concentrations are estimated to range between 11.0 and 23.0 at % for TEOS and 13.0 and 16.0 at % for HMDSN. For a constant deposition rate of 0.15 μm/minute, the OH peak area decreases with the precursor type in the following order: TEOS, TMDSO, HMDSO, HMDSN.

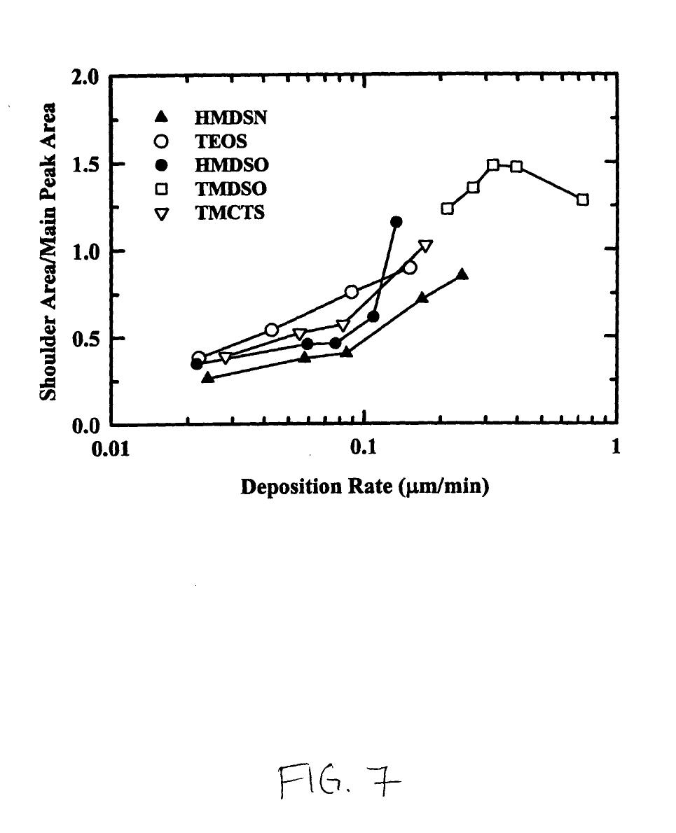

The ratio of the shoulder area of the Si—O stretching mode at approximately 1150/cm to the primary peak area at approximately 1075/cm has been correlated with a degree of porosity of silicon dioxide films. The trends associated with this ratio are illustrated in FIG. 7. In the graph, the y-axis values were calculated by deconvoluting the Si—O stretching region into two peaks located at 1075±5 and 1150±10/cm. An increase in porosity with growth rate is shown, and films deposited using TMDSO have higher degrees of porosity than those obtained with the other precursors. Of these, HMDSN produces the least porous material when compared with TEOS, HMDSO, and TMCTS at equal deposition rates.

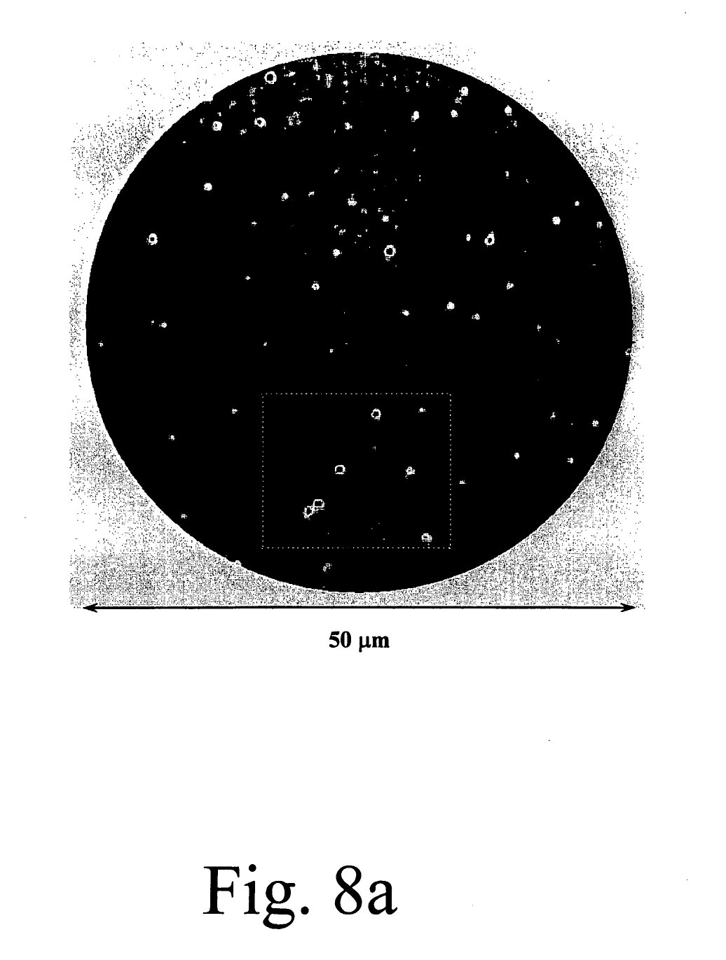

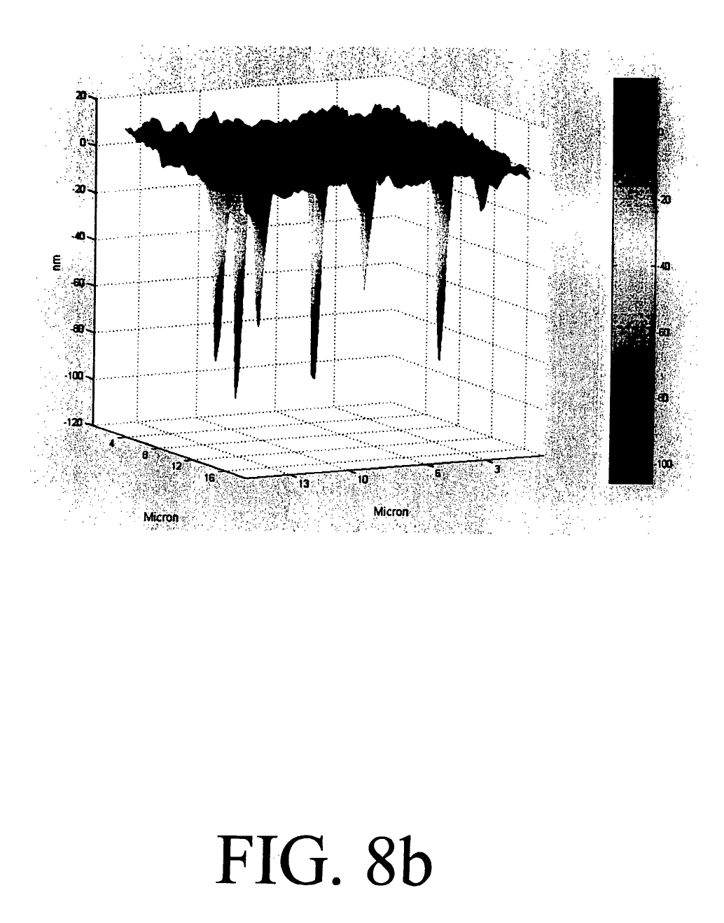

Further evidence of differences in the porosity of the films can be seen in images recorded with the optical profiler. FIGS. 8a and 8b show a three-dimensional surface image of a film and its magnified image, grown 650 nm thick at 0.21 μm/minute with TMDSO. A number of pits are shown on the surface that are approximately 1.0 μm in diameter and 40-130 nm deep. The number density of these pits is approximately 0.038/μm².

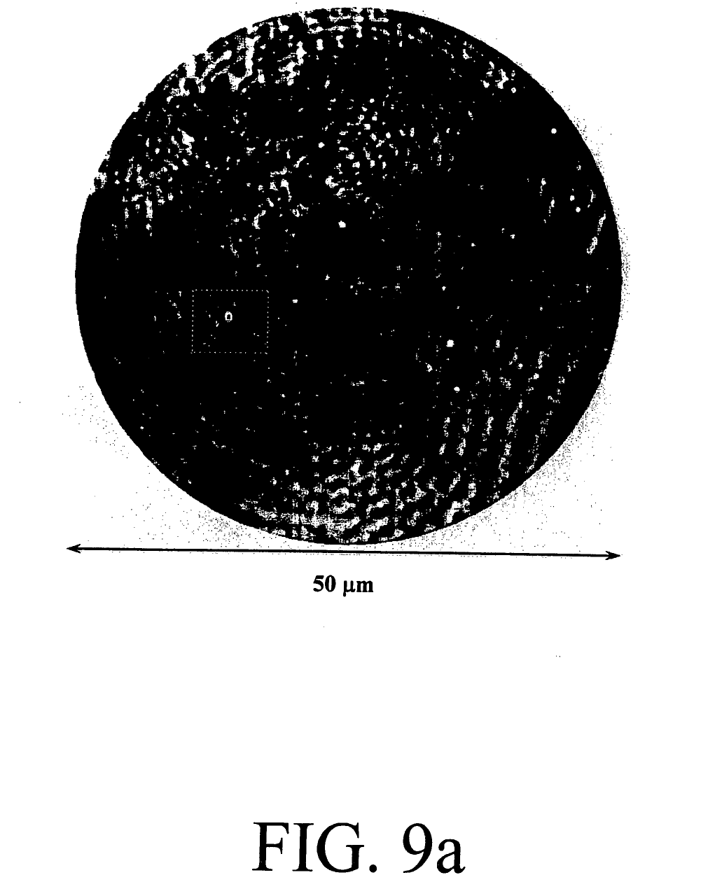

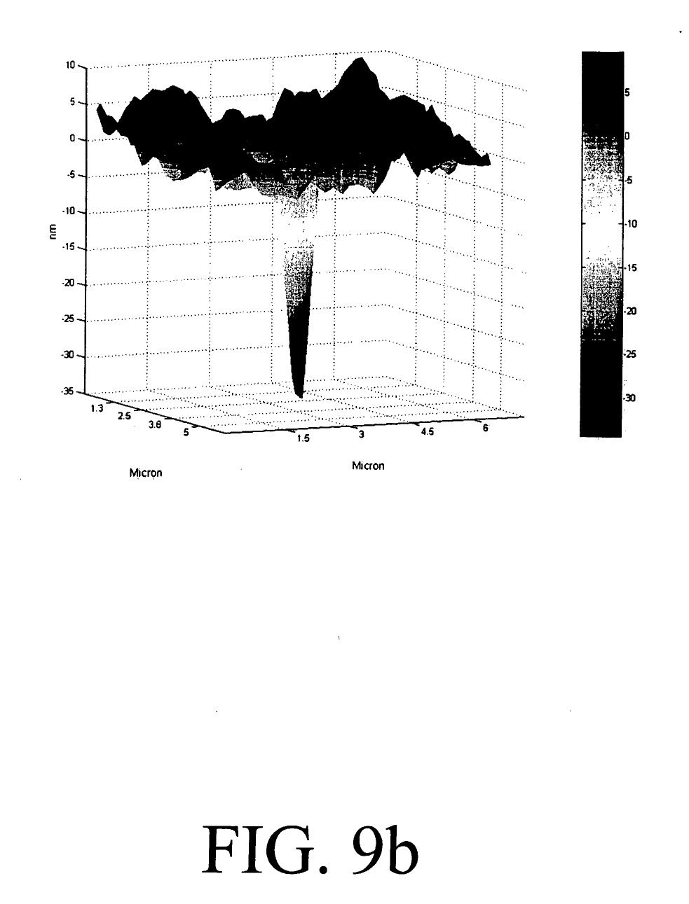

In contrast, a surface profile of a film of equal thickness, but deposited with HMDSN at a rate of 0.24 μm/minute, is shown in FIGS. 9a and 9b. This coating is significantly less porous, with the number density of pits measuring 0.014/μm² and their maximum depth only 35 nm.

Film composition was examined by infrared (IR) spectroscopy using a Bio-Rad™ FTS-41A with a DTGS detector. The IR spectra of the films were taken after 48 to 72 hours of exposure to the atmosphere. Absorbance spectra were obtained by taking the ratio of scans recorded before and after film deposition. Film morphology was analyzed with a three-dimensional optical surface profiler (Nona-Or 3DScope 2000 SEMI™).

These results show that the impurity concentration in the glass films depends on the organosilane precursor used and the deposition rate. The IR spectra presented in FIGS. 4 and 5 reveal significant quantities of unreacted methyl groups in material grown with TMDSO and HMDSO. For the former precursor, the number of CH₃ species rises dramatically when the growth rate is increased from 0.21 to 0.91 μm/minute. The hydroxyl content of the films in general increases with the deposition rate, as illustrated in FIG. 6. Nevertheless, at a rate of nearly 0.2 μm/minute, the glass film produced with HMDSN contains significantly less OH than the films grown using the other precursors. The trends in film porosity, as indicated by the ratio of the IR band at 1150/cm to that at 1075/cm (FIG. 7), mirror that of the hydroxyl content. Porosity increases with deposition rate, while at a fixed rate near 0.2 μm/minute, the films made with HMDSN are less porous than those made with other precursors, as shown in FIGS. 8a-9b.

Mechanical Performance

Preliminary scratch tests were performed on films deposited on silicon wafers. Samples were scratched with the corner of a ⅜ inch blade screwdriver held at approximately 45° from the surface normal. The blade corner was pressed firmly onto the film and dragged along the surface. The resulting scratch was rated as either shallow or deep. ‘Shallow’ scratches were barely visible to the eye and were less than 13 nm in depth, as measured by the step profiler. ‘Deep’ scratches were easily seen with the eye and penetrated at least 200 nm into the film.

Further qualitative tests were performed on films deposited on 2.5×2.5 cm² pieces of LEXAN (R) EXL1414 thermoplastic. The hardness was determined using a standard pencil test, as is known in the art. Abrasion resistance was characterized by rubbing the samples with steel wool and counting the number of scratches see with an optical microscope.

The scratch tests performed on silicon wafers indicate that the mechanical properties of the films deposited with HMDSN do not depend strongly on growth rate. Shallow scratch depths are measured over the entire range of rates from 0.023 to 0.24 μm/minute. For HMDSO, TMCTS, and TEOS, films deposited at rates below 0.1 μm/minute display good scratch resistance, with the screwdriver tip penetrating less than 13 nm into the films. Beyond 0.1 μm/minute, the hardness drops and deep scratch penetration is observed. For TMDSO, deep scratches are recorded over the whole range of deposition rates, between 0.21 and 0.91 μm/minute.

Further hardness testing was conducted on plastic substrates using HMDSN and TMDSO. Two deposition rates were investigated for each precursor: 0.075 and 0.24 μm/minute for HMDSN, and 0.21 and 0.91 μm/minute for TMDSO. In addition, coatings varying in thickness from 0.5 to 1.5 μm were examined. The results of the pencil hardness tests are presented in Table 2.

TABLE 2

| | Deposition | Film Thickness | Pencil |
|---|---|---|---|
| Precursor | Rate (μm/minute) | (μm) | Hardness |
| HMDSN | 0.075 | 0.5 | 4H |
| HMDSN | 0.075 | 1.0 | 4H |
| HMDSN | 0.24 | 0.5 | HB |
| HMDSN | 0.24 | 1.5 | 4H |
| TMDSO | 0.21 | 0.5 | HB |
| TMDSO | 0.21 | 1.5 | 3H |
| TMDSO | 0.91 | 0.5 | HB |
| TMDSO | 0.91 | 1.5 | HB |

With HMDSN at 0.075 μm/minute, the hardness does not show a dependence on thickness, as both films have a rating of 4H. However, there is a dependence on film thickness at 0.24 μm/minute. In this case, the hardness rating of the 0.5 μm-thick film is HB, while that of the 1.5 μm-thick film is 4H. With TMDSO, the hardness at 0.21 μm/minute also increases with film thickness. However, the material is softer and the 1.5 μm-thick film achieves only a 3H rating. At the maximum TMDSO deposition rate, the films exhibit a constant pencil hardness of HB, independent of thickness.

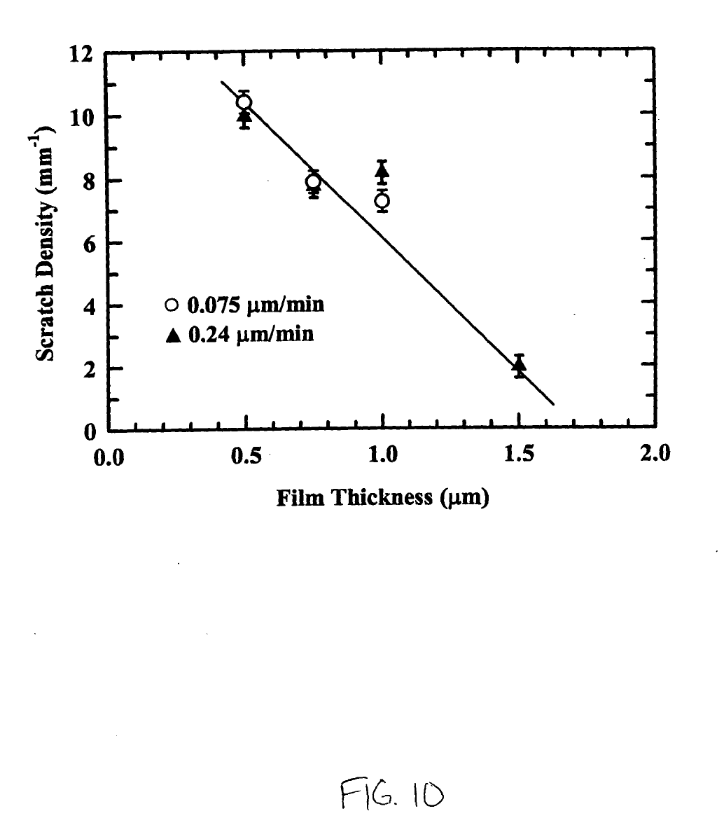

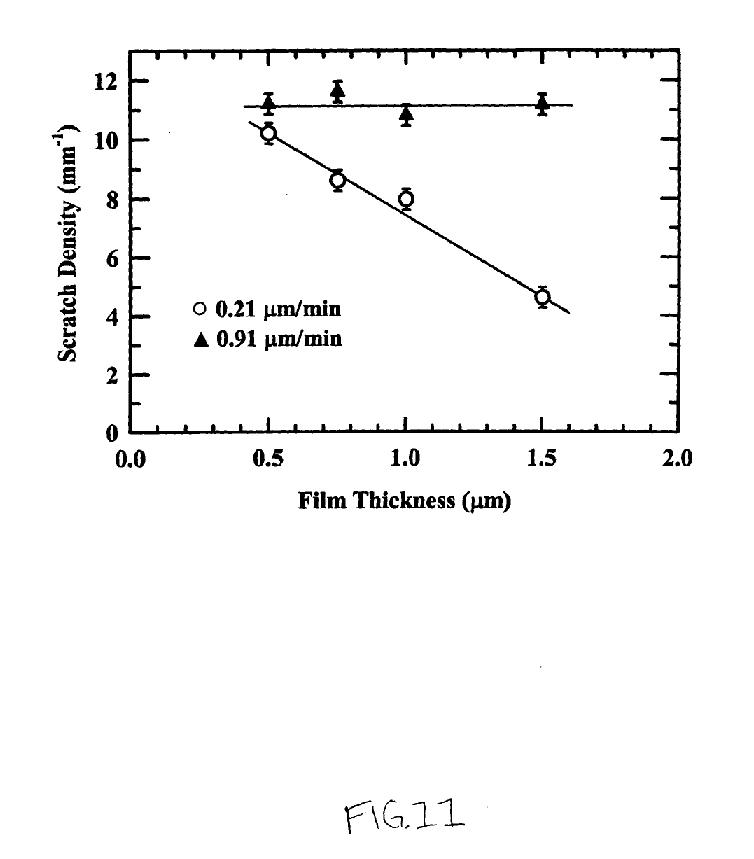

FIGS. 10 and 11 are the linear scratch densities caused by steel wool abrasion of films grown with HMDSN and TMDSO, respectively. In the former case, the number of scratches decreases as the film thickness increases, independent of growth rate. The 1.5 μm-thick film exhibits only 2 scratches per millimeter. On the other hand, films deposited with TMDSO show an effect of growth rate on abrasion resistance. At 0.91 μm/minute, the scratch density equals 11/mm for all films between 0.5 and 1.5 μm-thick. In contrast, at 0.21 μm/minute, the number of scratches declines with thickness to about 4/mm at 1.5 μm. Comparison of these data with the results presented in FIGS. 5-7 suggests that the poor abrasion resistance of the glass deposited at 0.91 μm/minute is most likely to be due to the incorporation of methyl groups into the film.

The test results shown in FIGS. 3-11 demonstrate that a chamberless, remote plasma deposition process can be used to generate abrasion-resistant glass coatings on even a thermally-sensitive substrate, like plastic. The properties of these coatings depend on the type and the amount of organosilane precursor fed to the process. The range of deposition rates achieved with different precursors spans two orders of magnitude. High quality films without visible defects, such as cracking or chalkiness, can be obtained with TEOS, TMCTS, and HMDSO at rates ranging from 0.02 to 0.15±0.02 μm/minute, and with HMDSN at rates of up to 0.24 μm/minute. Glass may be deposited with TMDSO at a significantly higher rate of 0.91 μm/minute. However, the coating exhibits poor abrasion resistance.

The impurity concentration in the glass coatings has a strong impact on their mechanical properties. Films generated with TMDSO at a rate of 0.91 μm/minute, and containing significant quantities of unreacted methyl groups, exhibit an HB value in pencil hardness, as well as high scratch densities after steel wool abrasion. The effect of hydroxyl impurities can be illustrated by comparing 1.5 μm-thick films grown at around 0.2 μm/minute using HMDSN and TMDSO. The former precursor generates less OH in the film, resulting in a 4H hardness and a scratch density of 4.5/mm. Previous work on plasma-assisted deposition of glass films using organosilane precursors has observed a strong effect of impurities on abrasion resistance. In these studies, it was concluded that impurities disrupt the Si—O—Si bonding network, leading to more porous films that are softer and more easily scratched. The mechanical properties of the glass films also improve with the thickness of the layers.

Although this invention has been described in certain specific embodiments, many additional modifications and variations would be apparent to those skilled in the art. It is therefore to be understood that this invention may be practiced otherwise than as specifically described. Thus, the present embodiments of the invention should be considered in all respects as illustrative and not restrictive, the scope of the invention to be determined by any claims supportable by this application and the claims' equivalents.

What is claimed is:

1. A system for deposition of coatings comprising:
a substrate in contact with air;
a plasma source having a housing surrounding a first electrode and a second electrode spaced from the first electrode, the first electrode electrically coupled to a signal generator such that gas between the first electrode and the second electrode is excited to form a plasma, the plasma emitted from the housing toward the substrate, wherein the plasma generates a substantially uniform flux of at least one reactive specie over an area larger than 1 cm²; and
a volatile precursor combined with the substantially uniform flux such that the volatile precursor is decomposed to deposit a substantially uniform coating on the substrate.

2. The system of claim 1, wherein the substantially uniform coating is an inorganic oxide.

3. The system of claim 2, wherein the inorganic oxide comprises oxygen and one or more elements selected from the group consisting of silicon, aluminum, gallium, indium, tin, lead, bismuth, zinc, cadmium, copper, silver, nickel, palladium, cobalt, iron, manganese, chromium, molybdenum, tungsten, vanadium, niobium, tantalum, titanium, zirconium, hafnium, scandium, yttrium, lanthanum, cerium, beryllium, and magnesium.

4. The system of claim 1, wherein the volatile precursor is a nonpyrophoric metalorganic precursor.

5. The system of claim 1, wherein the volatile precursor comprises silicon combined with a ligand containing at least one of the group of elements consisting of oxygen, carbon, hydrogen, or nitrogen.

6. The system of claim 1, wherein the volatile precursor is chosen from a group consisting of hexamethyldisilazane, hexamethyldisiloxane, tetramethyldisiloxane, tetramethylcyclotetrasiloxane, and tetraethoxysilane.

7. The system of claim 1, wherein the substantially uniform flux is at a temperature of less than 250° C.

8. The system of claim 1, wherein the substrate comprises at least one material of the group consisting of plastic, wood, metal, a semiconducting material, or glass.

9. The system of claim 1, wherein the air is at substantially atmospheric pressure.

10. A method of depositing a coating on a substrate comprising:
providing a substrate in contact with air;
providing a plasma source having a housing surrounding a first electrode and a second electrode spaced from the first electrode;
generating a plasma by applying a signal to the first electrode to excite gas between the first electrode and the second electrode such that a substantially uniform flux of at least one reactive specie is generated over an area larger than 1 cm²;
emitting the substantially uniform flux into the air and toward the substrate; and
depositing a coating on the substrate.

11. The method of claim 10, wherein the depositing comprises combining a volatile precursor with the substantially uniform flux such that the volatile precursor is decomposed to deposit a substantially uniform coating on the substrate.

12. The method of claim 11, wherein the volatile precursor is chosen from the group consisting of: hexamethyldisilazane, hexamethyldisiloxane, tetramethyldisiloxane, tetramethylcyclotetrasiloxane, and tetraethoxysilane.

13. The method of claim 10, wherein the coating comprises an inorganic oxide.

14. The method of claim 13, wherein the inorganic oxide is glass.

15. The method of claim 10, wherein the coating is deposited at a rate above 0.3 μm/minute.

16. The method of claim 10, wherein the substantially uniform flux is at a temperature of less than 250° C.

17. The method of claim 10, wherein the substrate comprises at least one material selected from the group consisting of plastic, wood, metal, a semiconducting material, and glass.

18. The method of claim 10, wherein the air is at substantially atmospheric pressure.

19. A coated substrate formed by a method comprising:
providing a substrate in contact with air;
providing a plasma source having a housing surrounding a first electrode and a second electrode spaced from the first electrode;
generating a plasma by applying a signal to the first electrode to excite gas between the first electrode and the second electrode such that a substantially uniform flux of at least one reactive specie is generated over an area larger than 1 cm²;
emitting the substantially uniform flux into the air and toward the substrate; and
depositing a coating on the substrate.

20. The coated substrate of claim 19, wherein the depositing comprises combining a volatile precursor with the substantially uniform flux such that the volatile precursor is decomposed to deposit a substantially uniform coating on the substrate.

21. The coated substrate of claim 20, wherein the volatile precursor is chosen from the group consisting of: hexamethyldisilazane, hexamethyldisiloxane, tetramethyldisiloxane, tetramethylcyclotetrasiloxane, and tetraethoxysilane.

22. The coated substrate of claim 19, wherein the coating comprises an inorganic oxide.

23. The coated substrate of claim 22, wherein the inorganic oxide is glass.

24. The coated substrate of claim 19, wherein the coating is deposited at a rate above 0.3 μm/minute.

25. The coated substrate of claim 19, wherein the substantially uniform flux is at a temperature of less than 250° C.

26. The coated substrate of claim 19, wherein the substrate comprises at least one material selected from the group consisting of plastic, wood, metal, a semiconducting material, and glass.

27. The coated substrate of claim 19, wherein the air is at substantially atmospheric pressure.
